(19) United States
(12) Patent Application Publication
(10) Pub. No.: US 2016/0231650 A1
(43) Pub. Date: Aug. 11, 2016

(54) PHOTOSENSITIVE LIGHT-SHIELDING PASTE AND PROCESS FOR PRODUCING LAMINATED PATTERN FOR TOUCH SENSOR

(71) Applicant: TORAY INDUSTRIES, INC., Tokyo (JP)

(72) Inventors: Miharu Tanabe, Otsu-shi (JP); Kazutaka Kusano, Otsu-shi (JP); Akihiko Tanaka, Otsu-shi (JP)

(73) Assignee: TORAY INDUSTRIES, INC., Tokyo (JP)

(21) Appl. No.: 15/022,048

(22) PCT Filed: Sep. 18, 2014
(86) PCT No.: PCT/JP2014/074716

§ 371 Date: Mar. 15, 2016

(30) Foreign Application Priority Data
Sep. 25, 2013 (JP) 2013-197991
Mar. 14, 2014 (JP) 2014-051261

(51) Int. Cl. G03F 7/039; G06F 3/041; G03F 7/32; G03F 7/40; G03F 7/16; G03F 7/20

(52) U.S. Cl. CPC G03F 7/039; G03F 7/16; G03F 7/20; G03F 7/322; G03F 7/40; G06F 3/041; G06F 2203/04103

(57) ABSTRACT

An object of the present invention is to provide a photosensitive light-shielding paste for producing a fine laminated pattern comprising a light-shielding layer and an electroconductive layer which functions as a substitute for ITO, and this photosensitive light-shielding paste is free from the problems of visible sensing electrode and reflection of the light. Provided is a photosensitive light-shielding paste comprising a pigment, a photosensitive organic compound, and a thermosetting compound wherein proportion of the pigment in the entire solid content is 5 to 50% by mass.

### TECHNICAL FIELD

The present invention relates to a photosensitive light-shielding paste and a process for producing a laminated pattern for a touch sensor.

### BACKGROUND ART

A touch screen is often used in devices such as mobile phone and personal digital assistant (PDA). In general, the touch screen is composed of a display section such as liquid crystal panel and a position input system such as touch sensor. This touch sensor is composed of a sensing electrode formed mainly in the display section of the display device and a conductive wiring provided in the vicinity of the display section. For the sensing electrode, a highly transparent indium tin oxide (hereinafter referred to as “ITO”) is widely used to thereby retain visibility of the display section.

However, indium which is the starting material of the ITO is an expensive rare earth metal, and its supply is unstable. In addition, indium has a relatively low electroconductivity, and its use for sensing electrode in the large touch screen to be incorporated, for example, in an electronic whiteboard has been associated with the problem of insufficient electroconductivity. In view of such situation, search for ITO substitute has been underway, and an exemplary material that has been developed is the one prepared by using a noble metal (Patent Document 1).

### PRIOR ART DOCUMENT

### Patent Document

### Patent Document 1: Japanese Unexamined Patent Publication (Kokai) No. 2013-924

### SUMMARY OF THE INVENTION

### Problems to be Solved by the Invention

When a material using a noble metal is used for the touch screen, the screen will suffer from the problem of reduced visibility of the display due to the so-called “visible electrode” wherein the pattern of the sensing electrode is exposed to view as well as the problem of light reflection.

In view of the situation as described above, an object of the present invention is to provide a photosensitive light-shielding paste for producing a fine laminated pattern comprising the light-shielding layer and the electroconductive layer which can be used in place of the ITO, and this photosensitive light-shielding paste is free from the problems of the visible sensing electrode and the light reflection.

### Means for Solving the Problems

In order to solve the problems as described above, the present invention provides a photosensitive light-shielding paste, a process for producing a laminated pattern for a touch sensor, a touch sensor, and a touch screen as described in the following (1) to (8).

(1) A photosensitive light-shielding paste comprising a pigment, a photosensitive organic compound, and a thermosetting compound wherein proportion of the pigment in the entire solid content is 5 to 50% by mass.
(2) A photosensitive light-shielding paste according to the above (1) wherein the pigment is an oxide of a metal selected from the group consisting of chromium, iron, cobalt, ruthenium, manganese, palladium, copper, nickel, magnesium and titanium or a carbon black.
(3) A photosensitive light-shielding paste according to the above (1) or (2) wherein the photosensitive organic compound and/or the thermosetting compound has a skeleton selected from the group consisting of bisphenol A skeleton, bisphenol F skeleton, biphenyl skeleton, and hydrogenated bisphenol A skeleton.
(4) A photosensitive light-shielding paste according to any one of the above (1) to (3) wherein the photosensitive organic compound has carboxyl group.
(5) A process for producing a laminated pattern for a touch sensor comprising the steps of

a first coating step wherein a photosensitive light-shielding paste comprising a pigment, a photosensitive organic compound, and a thermosetting compound is coated on a substrate to form a light-shielding coating film,

a second coating step wherein a photosensitive electroconductive paste comprising an electroconductive powder, a photosensitive organic compound, and a thermosetting compound is coated on the light-shielding coating film to form an electroconductive coating film, and

a step of forming a laminated pattern wherein the light-shielding coating film and the electroconductive coating film are together exposed and developed, and then subjected to either heating to a temperature of 100 to 300° C. or irradiation by a light beam of xenon flash lamp to thereby form the laminated pattern comprising a light-shielding layer and an electroconductive layer.

(6) A process for producing a laminated pattern for a touch sensor according to the above (5) wherein the line width of the laminated pattern is 2 to 9 μm.
(7) A touch sensor having the laminated pattern for a touch sensor produced by the production process of the above (5) or (6).
(8) A touch screen having the touch sensor of the above (7).

### Advantageous Effect of the Invention

The photosensitive light-shielding paste of the present invention enables production of a fine laminated pattern comprising the light-shielding layer and the electroconductive layer which can be used in place of the ITO, and this photosensitive light-shielding paste is free from the problems of the visible sensing electrode and the light reflection.

### DESCRIPTION OF PREFERRED EMBODIMENTS

The photosensitive light-shielding paste of the present invention is a photosensitive light-shielding paste containing a pigment, a photosensitive organic compound, and a thermosetting compound wherein proportion of the pigment in the entire solid content is 5 to 50% by mass. The term “entire solid content” as used herein means entire components of the photosensitive light-shielding paste excluding the solvent.

The photosensitive organic compound included in the photosensitive light-shielding paste of the present invention is a monomer, oligomer, or polymer containing unsaturated double bond. Exemplary monomers containing unsaturated double bond include acrylic monomers. Example acrylic monomers include acrylic monomers such as methyl acrylate, acrylic acid, 2-ethylhexyl acrylate, ethyl methacrylate, N-butyl acrylate, iso-butyl acrylate, iso-propane acrylate, glycidyl acrylate, N-methoxymethyl acrylamide, N-ethoxymethyl acrylamide, N-n-butoxymethyl acrylamide, N-isobutoxymethyl acrylamide, butoxytriethylene glycol acrylate, dicyclopentanyl acrylate, dicyclopentenyl acrylate, 2-hydroxyethyl acrylate, isobornyl acrylate, 2-hydroxypropyl acrylate, isodexyl acrylate, isooctyl acrylate, lauryl acrylate, 2-methoxyethyl acrylate, methoxyethyleneglycol acrylate, methoxydiethyleneglycol acrylate, octafluoropentyl acrylate, phenoxyethyl acrylate, stearyl acrylate, trifluoroethyl acrylate, acrylamide, aminoethyl acrylate, phenyl acrylate, phenoxyethyl acrylate, 1-naphthyl acrylate, 2-naphthyl acrylate, thiophenol acrylate, and benzylmercaptan acrylate; styrenes such as styrene, p-methylstyrene, o-methylstyrene, m-methylstyrene, α-methylstyrene, chloromethylstyrene, and hydroxymethylstyrene; γ-methacryloxypropyltrimethoxysilane, 1-vinyl-2-pyrrolidone, allylated cyclohexyl diacrylate, 1,4-butanediol diacrylate, 1,3-butylene glycol diacrylate, ethyleneglycol diacrylate, diethylene glycol diacrylate, triethylene glycol diacrylate, polyethylene glycol diacrylate, dipentaerythritol hexaacrylate, dipentaerythritol monohydroxy pentaacrylate, ditrimethylolpropane tetraacrylate, glycerol diacrylate, methoxylated cyclohexyl diacrylate, neopentyl glycol diacrylate, propylene glycol diacrylate, polypropylene glycol diacrylate, triglycerol diacrylate, and trimethylolpropane triacrylate; epoxy acrylate monomers such as acrylic acid adduct of ethyleneglycol diglycidyl ether having hydroxy group formed by ring opening of epoxy group by an unsaturated acid, an acrylic acid adduct of diethylene glycol diglycidyl ether, an acrylic acid adduct of neopentyl glycol diglycidyl ether, an acrylic acid adduct of glycerin diglycidyl ether, an acrylic acid adduct of bisphenol A diglycidyl ether, an acrylic acid adduct of bisphenol F, and an acrylic acid adduct of cresol novolac; and a compound which is the acrylic monomer having its acryl group substituted with methacryl group. Exemplary commercially available epoxy acrylates include epoxy esters 40EM, 70 PA, 80MFA, 3002M, and the like (products manufactured by Kyoeisha chemical Co., Ltd.), CN104, CN121, and the like (products manufactured by Sartomer Com), and EBECRYL 3702, EBECRYL 3700, EBECRYL 600, and the like (products manufactured by Daicel-Cytec Company, Ltd.).

Examples of the oligomer or polymer containing the unsaturated double bond include oligomers and polymers of an acrylic copolymer. Exemplary acrylic copolymers include copolymers containing an acrylic monomer in the copolymer component.

The photosensitive organic compound preferably contains carboxyl group. The acrylic copolymer or oligomer containing the carboxyl group can be obtained by using an unsaturated acid such as unsaturated carboxylic acid for the monomer. Exemplary unsaturated acids include acrylic acid, methacrylic acid, itaconic acid, crotonic acid, maleic acid, fumaric acid, vinyl acetate, and acid anhydrides thereof. Acid value of the resulting acrylic copolymer can be adjusted by changing the amount the unsaturated acid used.

An alkali-soluble acrylic copolymer having a reactive unsaturated double bond in the side chain can be obtained by reacting the carboxyl group in the acrylic copolymer with a compound having an unsaturated double bond such as glycidyl (meth)acrylate.

The acid value of the photosensitive organic compound is preferably in the range of 40 to 250 mg KOH/g to optimize the alkali-solubility of the photosensitive organic compound. When the acid value is less than 40 mg KOH/g, solubility of the soluble moiety will be reduced. On the other hand, development tolerance will be reduced when the acid value is in excess of 250 mg KOH/g. It is to be noted that the acid value can be measured according to JIS K 0070:1992.

The thermosetting compound in the photosensitive light-shielding paste of the present invention is a monomer, oligomer, or polymer having epoxy group. It is to be noted that the one having both the epoxy group and the unsaturated double bond in one molecule is classified as a photosensitive organic compound.

Examples of the polymer having the epoxy group include ethyleneglycol-modified epoxy resin, bisphenol A epoxy resin, brominated epoxy resin, bisphenol F epoxy resin, novolac epoxy resin, alicyclic epoxy resin, glycidyl amine epoxy resin, glycidyl ether epoxy resin, and heterocyclic epoxy resin.

Amount of the thermosetting compound added in relation to 100 parts by mass of the photosensitive organic compound is preferably 1 to 100 parts by mass, more preferably 10 to 80 parts by mass, and still more preferably 30 to 80 parts by mass. The adhesion will be improved when the amount added in relation to 100 parts by mass of the photosensitive organic compound is at least 1 part by mass. On the other hand, when the amount added in relation to 100 parts by mass of the photosensitive organic compound is up to 100 parts by mass, the resulting photosensitive light-shielding paste will exhibit high stability in the state of the coating film.

The photosensitive organic compound and/or thermosetting compound incorporated in the photosensitive light-shielding paste of the present invention preferably has a skeleton selected from the group consisting of bisphenol A skeleton, bisphenol F skeleton, biphenyl skeleton, and alicyclic skeleton. It is the presence of such skeleton in the photosensitive organic compound and the thermosetting compound that allows the light-shielding coating film and the electroconductive coating film retain their shape even in the heating. Of these, the preferably are those having an alicyclic skeleton, and more preferably those having a cyclohexane skeleton. The term “alicyclic structure” as used herein includes structures wherein carbon atoms are bonded in the shape of a ring excluding the aromatic ring. Exemplary alicyclic structures include cyclopropane skeleton, cyclobutane skeleton, cyclopentane skeleton, cyclohexane skeleton, cyclobutene skeleton, cyclopentene skeleton, cyclohexene skeleton, cyclopropane skeleton, cyclobutyne skeleton, cyclopentyne skeleton, cyclohexyne skeleton, and hydrogenated bisphenol skeleton. Examples of the photosensitive organic compound or the thermosetting compound having such skeleton or the compound used for their synthesis include hydrogenated bisphenol A, 1,1-cyclobutane dicarboxylic acid, 1,2,3,4-cyclobutane tetracarboxylic acid, 4,4-diamino-dicyclohexyl methane, isophorone diamine, dicyclohexyl methane 4,4′-diisocyanate, trans-4-methyl cyclohexyl isocyanate, Takenate 600 (1,3-bis(isocyanate methyl) cyclohexane) (manufactured by Mitsui Chemicals, Inc.), diisocyanic acid isophorone, 1,2-epoxycyclohexane, 1-vinyl-3,4-epoxycyclohexane, RIKARESIN DME-100 (1,4-cyclohexane dimethanol diglycidyl ether) (manufactured by New Japan Chemical Co., Ltd.), RIKARESIN HBE-100 (a polymer of 4,4′-isopropylidene dicyclohexanol and (chloromethyl)oxylan) (manufactured by New Japan Chemical Co., Ltd.), ST-4000D (an epoxy resin containing hydrogenated bisphenol A as its main component manufactured by Nippon Steel Chemical Co., Ltd.), 1,2:5,6-diepoxycyclooctane, PO adduct diacrylate of hydrogenated bisphenol A, EO adduct dimethacrylate of hydrogenated bisphenol A, PO adduct dimethacrylate of hydrogenated bisphenol A, 2-acryloyloxyethylhexahydrophthalic acid, dimethylol-tricyclodecane diacrylate, cyclohexyl acrylate, cyclohexyl methacrylate, tert-butylcyclohexyl acrylate, tert-butyl cyclohexyl methacrylate, isobornyl acrylate, dicyclopentenyl acrylate, dicyclopentenyloxyethyl acrylate, dicyclopentanyl acrylate, dicyclopentenyloxyethyl methacrylate, and dicyclopentanyl methacrylate. Of these, the preferred are those having hydrogenated bisphenol A skeleton.

The pigment incorporated in the photosensitive light-shielding paste of the present invention is a colored powder having its absorption in the visible range. The pigment is preferably an inorganic compound having the absorption in the visible range in view of the ease of optimizing the color, particle size, dispersion, and surface roughness of the powder which affect the light-shielding property. The term “inorganic compound” as used herein includes compounds composed of elements other than carbon and some simple carbon compounds. Exemplary such simple carbon compounds include carbon allotropes such as graphite and diamond, metal carbonates such as calcium carbonate, and salts of a metal carbide. Examples of the inorganic compound having the absorption in the visible range which can be used as a pigment include metal oxide, carbon black and acetylene black, Ketjen black, titanium black, carbon whisker, carbon nanotube, and the like, and the preferred are powders of an oxide of a metal selected from the group consisting of chromium, iron, cobalt, ruthenium, manganese, palladium, copper, nickel, magnesium, and titanium or a carbon black. Such metal oxide and carbon black may be used alone or as an oxide mixture or powder mixture. Exemplary such pigments include tricobalt tetroxide (Co₃O₄), ruthenium oxide (RuO₂), Cr₂O₃—CuO—Co₃O₄, CuO—Cr₂O₃—Mn₂O₃, and powder mixture thereof. Also included are the metal oxides as described above coated with other metal powder or a resin powder.

The pigment may preferably have a volume average particle diameter satisfying the following conditions to thereby enable fine patterning while realizing the light shielding ability with the pigment consistently distributed in the paste. The volume average particle diameter of the pigment is preferably at least 0.03 μm and more preferably at least 0.05 μm since the volume average particle diameter of less than 0.03 μm may result in the insufficient light shielding ability. On the other hand, the volume average particle diameter of the pigment is preferably up to 2 μm and more preferably up to 1 μm since the volume average particle diameter in excess of 2 μm may invite insufficient surface lubricity of the coating film prepared by coating the photosensitive light-shielding paste of the present invention as well as difficulty of the light beam used for the exposure passing through the coating film which may invite difficulty of forming the fine patterning. It is to be noted that the volume average particle diameter can be measured by dynamic light scattering.

Amount of the pigment added is preferably 5 to 50% by mass in relation to the entire solid content in the photosensitive light-shielding paste. When the amount of the pigment added in relation to the entire solid content is at least 5% by mass, formation of a dense coating film having a high light-shielding ability will be enabled. On the other hand, the amount of the pigment added in relation to the entire solid content in excess of 50% by mass may invite difficulty in the passing of the exposure light through the coating film and difficulty of the fine patterning as well as easy peeling of the pattern during the development.

Preferably, the photosensitive light-shielding paste of the present invention optionally contains a photoinitiator. A photoinitiator is a compound which generates a radical by undergoing decomposition by absorbing a short wavelength light such as UV or by hydrogen abstraction reaction. Exemplary photoinitiators include 1,2-octanedione, 1-[4-(phenylthio)-2-(O-benzoyloxime)], 2,4,6-trimethylbenzoyl-diphenyl-phosphine oxide, bis(2,4,6-trimethyl benzoyl)-phenylphosphine oxide, ethanone, 1-[9-ethyl-6-2(2-methylbenzoyl)-9H-carbazole-3-yl]-1-(O-acetyloxime), benzophenone, o-benzoylmethyl benzoate, 4,4′-bis(dimethylamino)benzophenone, 4,4′-bis(diethylamino)benzophenone, 4,4′-dichlorobenzophenone, 4-benzoyl-4′-methyl diphenyl ketone, dibenzyl ketone, fluorenone, 2,2′-diethoxy acetophenone, 2,2-dimethoxy-2-phenylacetophenone, 2-hydroxy-2-methyl propiophenone, p-t-butyldichloroacetophenone, thioxanthone, 2-methylthioxanthone, 2-chlorothioxanthone, 2-isopropylthio xanthone, diethylthioxanthone, benzyl, benzyl dimethyl ketal, benzyl-β-methoxy ethyl acetal, benzoin, benzoin methyl ether, benzoin butyl ether, anthraquinone, 2-t-butylanthraquinone, 2-amylanthraquinone, β-chloroanthraquinone, anthrone, benzanthrone, dibenzosuberone, methylene anthrone, 4-azidobenzalacetophenone, 2,6-bis(p-azidobenzylidene)cyclohexanone, 6-bis(p-azidobenzylidene)-4-methylcyclohexanone, 1-phenyl-1,2-butanedione-2-(o-methoxycarbonyl)oxime, 1-phenyl-propanedione-2-(o-ethoxycarbonyl)oxime, 1-phenyl-propanedione-2-(o-benzoyl) oxime, 1,3-diphenyl-propanetrione-2-(o-ethoxycarbonyl)oxime, 1-phenyl-3-ethoxy-propanetrione-2-(o-benzoyl)oxime, Michler's ketone, 2-methyl-[4-(methylthio)phenyl]-2-morpholino-1-propanone, naphthalene sulfonyl chloride, quinoline sulfonyl chloride, N-phenyl thioacrydone, 4,4′-azobisisobutyronitrile, diphenyl disulfide, benzthiazole disulfide, triphenylphosphine, camphorquinone, 2,4-diethyl thioxanthone, isopropylthioxanthone, carbon tetrabromide, tribromophenylsulfone, benzoin peroxide, and a combination of photoreducible dye such as eosine and methylene blue and a reducing agent such as ascorbic acid and triethanolamine.

Amount of the photoinitiator added is preferably 0.05 to 30 parts by mass and more preferably 5 to 20 parts by mass in relation to 100 parts by mass of the photosensitive organic compound. When the amount of the photoinitiator added in relation to 100 parts by mass of the photosensitive organic compound is at least 0.05 part by mass, the exposed part of the photosensitive light-shielding paste will have a higher density after the curing and this may result in the increase of the residual film after the development. On the other hand, when the amount of the photoinitiator added in relation to 100 parts by mass of the photosensitive organic compound is up to 30 parts by mass, excessive light absorption on the surface of the coating film obtained by coating the photosensitive light-shielding paste will be suppressed. This may suppress loss of the adhesion with the substrate due to the reversely tapered shape of the pattern formed.

The photosensitive light-shielding paste of the present invention may include a sensitizer with the photoinitiator.

Exemplary sensitizers include 2,4-diethylthioxanthone, isopropylthioxanthone, 2,3-bis(4-diethylaminobenzal)cyclopentanone, 2,6-bis(4-dimethylaminobenzal)cyclohexanone, 2,6-bis(4-dimethylaminobenzal)-4-methylcyclohexanone, Michler's ketone, 4,4-bis(diethylamino)benzophenone, 4,4-bis(dimethylamino)chalcone, 4,4-bis(diethylamino)chalcone, p-dimethylaminocinnamylidene indanone, p-dimethylaminobenzylidene indanone, 2-(p-dimethylaminophenylvinylene)isonaphtothiazole, 1,3-bis(4-dimethylaminophenylvinylene)isonaphtothiazole, 1,3-bis(4-dimethylaminobenzal)acetone, 1,3-carbonylbis(4-diethylaminobenzal)acetone, 3,3-carbonylbis(7-diethylaminocoumarin), N-phenyl-N-ethylethanolamine, N-phenylethanolamine, N-tolyldiethanolamine, isoamyl dimethylaminobenzoate, isoamyl diethylaminobenzoate, 3-phenyl-5-benzoylthiotetrazole, and 1-phenyl-5-ethoxycarbonylthiotetrazole.

Amount of the sensitizer added in relation to 100 parts by mass of the photosensitive organic compound is preferably 0.05 to 10 parts by mass and more preferably 0.1 to 10 parts by mass. The photosensitivity will be improved when the amount added in relation to 100 parts by mass of the photosensitive organic compound is at least 0.05 part by mass. On the other hand, when the amount added in relation to 100 parts by mass of the photosensitive organic compound is up to 10 parts by mass, excessive light absorption on the surface of the coating film obtained by coating the photosensitive light-shielding paste will be suppressed. This may suppress loss of the adhesion with the substrate due to the reversely tapered shape of the pattern formed.

The photosensitive light-shielding paste of the present invention may contain a carboxylic acid or its anhydride. Exemplary carboxylic acids include acetic acid, propionic acid, succinic acid, maleic acid, phthalic acid, 1,2,3,6-tetrahydrophthalic acid, 3,4,5,6-tetrahydrophthalic acid, hexahydrophthalic acid, 4-methylhexahydrophthalic acid, methylbicyclo[2.2,1]heptane-2,3-dicarboxylic acid, ethyleneglycol bisanhydrotrimellitate, glycerin bisanhydrotrimellitate monoacetate, tetrapropenylsuccinic acid, octenylsuccinic acid, 3,3′,4,4′-diphenylsulfonetetracarboxylic acid, 1,3,3a,4,5,9b-hexahydro-5(tetrahydro-2,5-dioxo-3-furanyl)naphtho[1,2-c]furan-1,3-dione, 1,2,3,4-butane tetracarboxylic acid, cyclohexane-1,2,3,4-tetracarboxylic acid, FLOWLEN G-700 (manufactured by Kyoeisha Chemical Co., Ltd.), FLOWLEN G-900 (manufactured by Kyoeisha Chemical Co., Ltd.), BYK-P105 (manufactured by BYK-Chemie), KD-4 (manufactured by Croda), KD-8 (manufactured by Croda), KD-9 (manufactured by Croda), KD-12 (manufactured by Croda), KD-15 (manufactured by Croda), JP-57 (manufactured by Croda), and PA-111 (manufactured by Ajinomoto Fine-Techno Co., Inc.). Exemplary carboxylic anhydrides include acetic anhydride, propionic anhydride, succinic anhydride, maleic anhydride, phthalic anhydride, 1,2,3,6-tetrahydrophthalic anhydride, 3,4,5,6-tetrahydrophthalic anhydride, hexahydrophthalic anhydride, 4-methylhexahydrophthalic anhydride, methylbicyclo[2.2,1]heptane-2,3-dicarboxylic anhydride, ethyleneglycol bisanhydrotrimellitate, glycerin bisanhydrotrimellitate monoacetate, tetrapropenylsuccinic anhydride, octenylsuccinic anhydride, 3,3′,4,4′-diphenylsulfonetetracarboxylic acid anhydride, 1,3,3a,4,5,9b-hexahydro-5(tetrahydro-2,5-dioxo-3-furanyl)naphto[1,2-c]furan-1,3-dione, 1,2,3,4-butanetetracarboxylic di anhydride, and cyclohexane-1,2,3,4-tetracarboxylic 3,4-anhydride.

Amount of the carboxylic acid or the acid anhydride added in relation to 100 parts by mass of the photosensitive organic compound is preferably 0.5 to 30 parts by mass and more preferably 1 to 20 parts by mass. Affinity to the developer solution will be improved to enable good patterning when the amount of the carboxylic acid or the acid anhydride added in relation to 100 parts by mass of the photosensitive organic compound is at least 0.5 part by mass. On the other hand, when the amount of the carboxylic acid or the acid anhydride added in relation to 100 parts by mass of the photosensitive organic compound is up to 30 parts by mass, development margin and adhesion at high temperature and high humidity will be improved.

The photosensitive light-shielding paste of the present invention may include a solvent for the purpose of adjusting its viscosity. Incorporation of a solvent is preferable in view of adjusting the paste viscosity. Exemplary solvents include N,N-dimethylacetamide, N,N-dimethylformamide, N-methyl-2-pyrrolidone, dimethylimidazolidine, dimethyl sulfoxide, diethylene glycol monoethyl ether, diethylene glycol monoethyl ether acetate (hereinafter referred to as “DMEA”), diethylene glycol monomethyl ether acetate, γ-butyrolactone, ethyl lactate, 1-methoxy-2-propanol, 1-ethoxy-2-propanol, ethyleneglycol mono-N-propyl ether, diacetone alcohol, tetrahydrofurfuryl alcohol, and propylene glycol monomethyl ether acetate. The photosensitive light-shielding paste of the present invention may also include plasticizer, levelling agent, surfactant, silane coupling agent, antifoaming agent, stabilizer, and the like to the extent not adversely affecting the desired property.

Exemplary plasticizers include dibutyl phthalate, dioctyl phthalate, polyethylene glycol, and glycerin.

Exemplary levelling agents include specialty vinyl polymers and specialty acryl polymers.

Exemplary silane coupling agents include methyltrimethoxysilane, dimethyldiethoxysilane, phenyltriethoxysilane, hexamethyldisilazane, 3-methacryloxypropyltrimethoxysilane, 3-glycidoxypropyltrimethoxysilane, and vinyltrimethoxysilane.

Exemplary stabilizers include benzotriazole derivatives, benzophenone derivatives, salicylic acid derivatives, cyanoacrylate derivatives, TINUVIN 109, TINUVIN 234, TINUVIN 328, TINUVIN 329, TINUVIN 384-2, and TINUVIN 571 (products manufactured by NAGASE & CO., LTD.), EVERSORB 75, EVERSORB 76, EVERSORB 81, EVERSORB 109, and EVERSORB 234 (products manufactured by Sort Co., Ltd.), Adekastab LA-38 (manufactured by ADEKA), Sumisorb 130, Sumisorb 250, Sumisorb 340, and Sumisorb 350 (products manufactured by Sumika Chemtex Company), and compounds having the primary to tertiary amino group. Exemplary compounds having the primary to tertiary amino group include N-(2-aminoethyl)piperazine, 1-(2-aminoethyl)-4-methylpiperazine hydrochloride, 6-amino-1-methyluracil, polyethyleneimine, and octadecyl isocyanate-modified polyethyleneimine, and propylene oxide-modified polyethyleneimine.

The photosensitive light-shielding paste of the present invention may be produced, for example, by using a disperser or a kneader such as three rolls, ball mill, or planetary ball mill.

The process for producing a laminated pattern for a touch sensor of the present invention comprises the steps of a first coating step wherein a photosensitive light-shielding paste comprising a pigment, a photosensitive organic compound, and a thermosetting compound is coated on a substrate to form a light-shielding coating film; a second coating step wherein a photosensitive electroconductive paste comprising an electroconductive powder, a photosensitive organic compound, and a thermosetting compound is coated on the light-shielding coating film to form an electroconductive coating film; and a step of forming a laminated pattern wherein the light-shielding coating film and the electroconductive coating film are together exposed and developed, and then subjected to either heating to a temperature of 100 to 300° C. or irradiation by a light beam of xenon flash lamp to thereby form the laminated pattern comprising a light-shielding layer and an electroconductive layer.

The photosensitive light-shielding paste used in the first coating step contains a pigment, a photosensitive organic compound, and a thermosetting compound, and among these, the preferred are those containing an oxide of a metal selected from the group consisting of chromium, iron, cobalt, ruthenium, manganese, palladium, copper, nickel, magnesium, and titanium or carbon black as a pigment.

Exemplary substrates used in the first coating step include polyethylene terephthalate film (hereinafter referred as “PET film”), polyimide film, polyester film, aramid film, epoxy resin substrate, polyetherimide resin substrate, polyetherketone resin substrate, polysulfone resin substrate, glass substrate, silicon wafer, alumina substrate, aluminum nitride substrate, silicon carbide substrate, substrate formed with a decorative layer, and substrate formed with an insulating layer.

Exemplary methods used for coating the photosensitive light-shielding paste on the substrate include rotary coating using a spinner, spray coating, roll coating, screen printing, and coating using a blade coater, die coater, calendar coater, meniscus coater or bar coater. The thickness of the resulting light-shielding coating film may be adequately determined depending on the coating method, the entire solid content or viscosity of the photosensitive light-shielding paste, or the like. The preferable thickness, however, is a thickness such that the thickness of the film after the drying is 0.1 to 10 μm. It is to be noted that the film thickness can be measured, for example, by using a probe-type surface profiler such as SURFCOM (Registered trademark) 1400 (manufactured by TOKYO SEIMITSU CO., LTD.). More specifically, the film thickness was respectively measured at 3 randomly selected positions by using a probe-type surface profiler (length measured, 1 mm; scanning speed, 0.3 mm/sec), and their average was used for the average film thickness.

The resulting light-shielding coating film is preferably dried to remove the solvent by volatilization before subjecting the light-shielding coating film to the second coating step. Exemplary methods used for the removal of the solvent by volatilization include drying by heat conduction using an oven, hot plate, or the like, electromagnetic wave using a UV lamp, infrared heater, or halogen heater, drying by heat using a microwave, and vacuum drying. Preferable heating temperature is 50 to 120° C., and preferable heating time is 1 minute to several hours.

The photosensitive electroconductive paste used in the second coating step contains an electroconductive powder, a photosensitive organic compound, and a thermosetting compound. The photosensitive organic compound and the thermosetting compound included in the photosensitive electroconductive paste are preferably the same as the photosensitive organic compound and the thermosetting compound included in the photosensitive light-shielding paste. By using the same photosensitive organic compound and thermosetting compound, thermal shrinkage of the light-shielding layer and the electroconductive layer will be approximately the same in the heating of the laminated pattern comprising the light-shielding layer and the electroconductive layer obtained in the subsequent step, and the deformation, delamination, and the like of the pattern will be thereby suppressed.

Examples of the electroconductive powder incorporated in the photosensitive electroconductive paste include powder of silver, gold, copper, platinum, lead, tin, nickel, aluminum, tungsten, molybdenum, ruthenium oxide, chromium, and titanium; powder of an alloy of such metal; mixture of such powder; and powders having the surface coated with such metal. In view of the electroconductivity, the preferred are silver, copper, and gold, and in view of the cost and stability, the more preferred is silver.

The electroconductive powder may preferably have a volume average particle diameter of 0.05 to 2 μm, and more preferably 0.05 to 1 μm in order to enable fine patterning. When the volume average particle diameter of the electroconductive powder is in excess of 2 μm, transmission of the beam used for the exposure through the coating film will be difficult, and the fine patterning may become difficult. It is to be noted that the volume average particle diameter of the electroconductive powder can be measured by dynamic light scattering as in the case of the pigment.

The electroconductive powder is preferably added at an amount of 60 to 95% by mass in relation to the entire solid content of the photosensitive electroconductive paste. When the addition amount in relation to the entire solid content is at least 60% by mass, the resulting electroconductive layer will exhibit reduced specific resistance as well as reduced risk of line breakage. On the other hand, when the addition amount in relation to the entire solid content is in excess of 95% by mass, transmission of the beam used for the exposure through the coating film will be difficult, and the fine patterning may become difficult. The term “solid content” as used herein is the same as the one used in the photosensitive light-shielding paste.

As in the case of the photosensitive light-shielding paste of the present invention, the photosensitive electroconductive paste may contain an additive such as a photoinitiator, sensitizer, carboxylic acid or its acid anhydride, plasticizer, levelling agent, surfactant, silane coupling agent, antifoaming agent, or stabilizer, or a solvent.

Exemplary methods used for coating the photosensitive electroconductive paste on the light-shielding coating film include the methods described as the method for coating the photosensitive light-shielding paste on the substrate. Film thickness of the resulting electroconductive coating film may be adequately determined on the basis of the method used for the coating, concentration of the entire solid content or viscosity of the photosensitive electroconductive paste, or the like. The film thickness, however, is preferably a thickness resulting in the dried film having a film thickness in the range of 0.1 to 10 μm.

The electroconductive coating film is preferably dried to remove the solvent by volatilization before the laminate pattern formation step of the resulting electroconductive coating film. Exemplary methods used for removing the solvent by volatilization include those used for the light-shielding coating film.

In the laminated pattern formation step, the laminated light-shielding coating film and the electroconductive coating film are processed by photolithography. More specifically, in the laminated pattern formation step, the laminated light-shielding coating film and the electroconductive coating film are simultaneously exposed and developed, and then subjected to heating at 100 to 300° C. or irradiation with the xenon flash lamp to thereby form the laminated pattern comprising the light-shielding layer and the electroconductive layer.

Exemplary preferable sources of the light used for the exposure include i-ray (365 nm), h-ray (405 nm), or g-ray (436 nm) of mercury lamp. A xenon flash lamp may also be used as the light source of the exposure.

After the simultaneous exposure of the light-shielding coating film and the electroconductive coating film, the desired pattern is formed by simultaneously developing the light-shielding coating film and the electroconductive coating film by using a developer solution and removing the unexposed parts by dissolution. Examples of the developer solution used in alkaline developing include an aqueous solution of tetramethylammonium hydroxide, diethanolamine, diethylaminoethanol, sodium hydroxide, potassium hydroxide, sodium carbonate, potassium carbonate, triethylamine, diethylamine, methylamine, dimethylamine, acetic acid dimethylamino ethyl, dimethylaminoethanol, dimethylamino ethyl methacrylate, cyclohexylamine, ethylenediamine, or hexamethylenediamine; which is optionally supplemented with a polar solvent such as N-methyl-2-pyrrolidone, N,N-dimethylformamide, N,N-dimethyl acetamide, dimethyl sulfoxide, or γ-butyrolactone, an alcohol such as methanol, ethanol, or isopropanol, an ester such as ethyl lactate or propylene glycol monomethyl ether acetate, a ketone such as cyclopentanone, cyclohexanone, isobutyl ketone, or methyl isobutyl ketone, and/or, a surfactant. Examples of the developer solution used in organic development include polar solvents such as N-methyl-2-pyrrolidone, N-acetyl-2-pyrrolidone, N,N-dimethylacetamide, N,N-dimethylformamide, dimethyl sulfoxide, and hexamethyl phosphortriamide; and mixed solutions of such polar solvent with methanol, ethanol, isopropyl alcohol, xylene, water, methyl carbitol, or ethyl carbitol.

Exemplary methods used for the development include spraying of the developer solution to the coating film surface while stopping or rotating the substrate, immersing of the substrate in the developer solution, and ultrasonication while immersing the substrate in the developer solution.

The pattern obtained by the development may be subjected to the rinsing treatment by rinsing solution. Examples of the rinsing solution include water and aqueous solutions prepared by adding an alcohol such as ethanol or isopropyl alcohol, an ester such as ethyl lactate or propylene glycol monomethyl ether acetate, or the like to the water.

The resulting laminate of the light-shielding film and the electroconductive film is subjected to heating at 100 to 300° C. or irradiation by xenon flash lamp to form the laminated pattern comprising the light-shielding layer and the electroconductive layer. Hardness of the laminated pattern formed is increased by the heating at 100 to 300° C. or the irradiation by xenon flash lamp, and cracking, peeling, and the like caused by the contact with other members are thereby suppressed, and the adhesion with the substrate is also improved by such treatment.

Exemplary methods used for the heating include dry heating by oven, inert oven, hot plate, infrared, or the like.

The light beam from the xenon flash lamp is irradiated preferably by pulse irradiation. The term “pulse irradiation” as used herein means the method of irradiation wherein continuous irradiation and intermittent irradiation are alternately repeated from moment to moment. The pulse irradiation is preferable in view of the capability of irradiating a light weaker than the continuous irradiation and the resulting capability of suppressing drastic degeneration of the electroconductive pattern. Such pulse irradiation is an effective means when improvement in the production efficiency, prevention of the excess light scattering, prevention of the substrate damage, and the like are desired. More specifically, combination of the pulse irradiation in a total irradiation time of 0.01 to 10000 msec is preferable. If desired, a light beam including emission line may be irradiated in addition to the light beam from the xenon flash lamp. Such simultaneous irradiation of the light beam including the emission line may be conducted, for example, by using a mercury xenon lamp or by simultaneous irradiation from the xenon lamp and the mercury lamp.

Energy amount of the light beam irradiated from the xenon flash lamp may be adequately determined depending on the type of the substrate, thickness and line width of the electroconductive pattern formed, and the like. The energy amount, however, is preferably 300 to 2500 mJ/cm² in view of preventing the damage of the substrate which liable to deterioration. It is to be noted that the energy amount and irradiation time of the light beam irradiated from the xenon flash lamp may be different between the display area and the decorative area.

In the meanwhile, the electroconductivity of the resulting pattern may be developed by the combination of heating at 100 to 300° C. and irradiation by the beam from the xenon flash lamp.

The thus formed laminated pattern may preferably have a line width of 2 to 9 μm. When the line width is less than 2 μm, the electroconductive layer will suffer from an insufficient electroconductivity as well as an increased risk of line breakage. On the other hand, the line width in excess of 9 μm may invite loss of the visibility of the display section.

The pattern produced by using the photosensitive light-shielding paste of the present invention is preferable for use as a sensing electrode of a touch sensor which is one of the members included in a touch screen. The systems adopted in touch screens include resistive membrane, optical, electromagnetic induction, and capacitive systems, and the laminated pattern of the present invention can be more preferably used in capacitive touch screens.

### EXAMPLES

The present invention is hereinafter described in further detail by referring to Examples and Comparative Examples which by no means limit the scope of the present invention.

The procedures used for evaluation in the Examples and Comparative Examples are as described below.

### <Evaluation of Patterning Ability>

The photosensitive light-shielding paste was coated on a glass substrate to a dry thickness of 3 to 4 μm by screen printing, and the coating was dried in an IR (infrared) heater furnace at 90° C. for 10 minutes to obtain a light-shielding coating film. Next, the photosensitive electroconductive paste was coated on the light-shielding coating film to a dry thickness of 3 to 4 μm by screen printing, and the coating was dried in the IR heater furnace at 90° C. for 5 minutes.

Next, the dried light-shielding coating film was exposed and developed through a photomask having a light-transmitting width of 3 μm and then heated in the IR hater furnace at 140° C. for 30 minutes to obtain the laminated pattern. The exposure was conducted by using an exposure system (PEM-6M manufactured by Union Optical Co., Ltd.) to an exposure of 1000 mJ/cm² (in terms of wavelength at 365 nm) (all ray exposure), and the development was conducted by immersing the substrate in 0.2% Na₂CO₃ solution for 30 seconds followed by rinsing treatment by ultrapure water.

The resulting laminated pattern was observed by an optical microscope to evaluate pattern line width increasing and pattern straightness. The pattern line width increasing was evaluated “pass”, when the line width was up to 9 μm. The straightness of the pattern was evaluated “pass” when winding of the laminated pattern or breakage of the laminated pattern was absent.

### <Evaluation of Line Resistance>

A laminated pattern was formed by repeating the procedure of the evaluation of the patterning ability. A resistance meter was connected to opposite ends of the resulting laminated pattern to measure the line resistance.

### <Evaluation of Light-Shielding Property>

The photosensitive light-shielding paste was coated on a glass substrate so that the film thickness of the dried film was 3 to 4 μm, and the resulting light-shielding coating film was dried in the IR heater furnace at 90° C. for 10 minutes to obtain a light-shielding coating film. Next, the photosensitive electroconductive paste was coated on the dried light-shielding coating film so that the film thickness of the dried film was 3 to 4 μm, and the resulting coating film was dried in the IR heater furnace at 90° C. for 10 minutes. After exposing the entire surface, heating in the IR heater furnace at 140° C. was conducted for 30 minutes to obtain the substrate for use in the evaluation. The conditions used in the exposure were similar to those used in the evaluation of the patterning ability. L* value was measured from the rear side of the resulting evaluation substrate by using a spectrophotometer (CM-2500d manufactured by KONICA MINOLTA, INC.), and the one having the L* value of <35 (less than 35) was evaluated “pass”. It is to be noted that the L* of 100 represents pure white and 0 represents black.

### <Evaluation of Adhesion to the Substrate>

The photosensitive light-shielding paste was coated on a glass substrate so that the film thickness of the dried film is 3 to 4 μm, and the resulting light-shielding coating film was dried in the IR heater furnace at 100° C. for 5 minutes. After exposing the entire surface, heating in the IR heater furnace at 140° C. was conducted for 30 minutes. The conditions used in the exposure were similar to those used in the evaluation of the patterning ability. The sample was cross-hatched (10×10) at an interval of 1 mm with a cutter and placed in a constant-temperature, constant-humidity tank SH-661 (manufactured by ESPEC Corp.) at a temperature of 85° C. and relative humidity of 85% for 240 hours. A self-adhesive tape (manufactured by Nichiban Co., Ltd.) was attached to the entire cross-hatched area of the sample taken out of the tank, and after peeling the tape, remaining squares were counted. The sample with 90 or more remaining squares was evaluated “pass”.

The materials use in the Examples and Comparative Examples are as described below.

### Photosensitive Organic Compound

### Synthetic Example 1

### Photosensitive Organic Compound (1)

Copolymerization ratio (based on mass):ethyl acrylate (hereinafter referred to as “EA”)/2-ethylhexyl methacrylate (hereinafter referred to as “2-EHMA”)/styrene (hereinafter referred to as “St”)/glycidyl methacrylate (hereinafter referred to as “GMA”)/acrylic acid (hereinafter referred to as “AA”)=20/40/20/5/15.

150 g of DMEA was charged in a reaction vessel of nitrogen atmosphere, and the temperature was raised to 80° C. by using an oil bath. To DMEA, a mixture comprising 20 g of EA, 40 g of 2-EHMA, 20 g of St, 15 g of AA, 0.8 g of 2,2′-azobisisobutyronitrile, and 10 g of diethylene glycol monoethyl ether acetate was added dropwise in 1 hour. After completing the dropwise addition, polymerization reaction was allowed to take place for another 6 hours. 1 g of hydroquinone monomethyl ether was then added to terminate the polymerization reaction, and a mixture comprising 5 g of GMA, 1 g of triethylbenzylammonium chloride, and 10 g of DMEA was then added dropwise for 0.5 hours. After the completion of the dropwise addition, the mixture was then allowed to undergo an addition reaction for 2 hours. The resulting reaction solution was purified by using methanol to remove the impurity which had not undergone the reaction, and the solution was dried under vacuum for another 24 hours to obtain photosensitive organic compound (1). The photosensitive organic compound (1) had an acid value of 103 mg KOH/g.

### Synthetic Example 2

### Photosensitive Organic Compound (2)

Copolymerization ratio (based on mass):tricyclodecane dimethanol diacrylate (IRR214-K manufactured by Daicel-Cytec Company, Ltd.)/modified bisphenol A diacrylate (EBECRYL150 manufactured by Daicel-Cytec Company, Ltd.)/St/AA=25/40/20/15.

150 g of DMEA was charged in a reaction vessel of nitrogen atmosphere, and the temperature was raised to 80° C. by using an oil bath. To DMEA, a mixture comprising 25 g of tricyclodecane dimethanol diacrylate (IRR214-K), 40 g of modified bisphenol A diacrylate (EBECRYL150), 20 g of St, 15 g of AA, 0.8 g of 2,2′-azobisisobutyronitrile, and 10 g of DMEA was added dropwise in 1 hour. After completing the dropwise addition, polymerization reaction was allowed to take place for another 6 hours. 1 g of hydroquinone monomethyl ether was then added to terminate the polymerization reaction. The resulting reaction solution was purified by using methanol to remove the impurity which had not undergone the reaction, and the solution was dried under vacuum for another 24 hours to obtain photosensitive organic compound (2). The photosensitive organic compound (2) had an acid value of 89 mg KOH/g.

### Synthetic Example 3

### Photosensitive Organic Compound (3)

Copolymerization ratio (based on mass):ethylene oxide-modified bisphenol A diacrylate (FA-324A manufactured by Hitachi Chemical Company, Ltd.)/EA/GMA/AA=50/10/5/15

150 g of DMEA was charged in a reaction vessel of nitrogen atmosphere, and the temperature was raised to 80° C. by using an oil bath. To DMEA, a mixture comprising 50 g of ethylene oxide-modified bisphenol A diacrylate (FA-324A), 20 g of EA, 15 g of AA, 0.8 g of 2,2′-azobisisobutyronitrile, and 10 g of diethylene glycol monoethyl ether acetate (DMEA) was added dropwise in 1 hour. After completing the dropwise addition, polymerization reaction was allowed to take place for another 6 hours. 1 g of hydroquinone monomethyl ether was then added to terminate the polymerization reaction, and a mixture comprising 5 g of GMA, 1 g of triethylbenzylammonium chloride, and 10 g of DMEA was then added dropwise for 0.5 hours. After the completion of the dropwise addition, the mixture was then allowed to undergo an addition reaction for 2 hours. The resulting reaction solution was purified by using methanol to remove the impurity which had not undergone the reaction, and the solution was dried under vacuum for another 24 hours to obtain photosensitive organic compound (3). The photosensitive organic compound (3) had an acid value of 96 mg KOH/g.

### Synthetic Example 4

### Photosensitive Organic Compound (4)

Copolymerization ratio (based on mass):difunctional epoxy acrylate monomer (epoxy ester 3002A manufactured by Kyoeisha Chemical Co., Ltd)/difunctional epoxy acrylate monomer (epoxy ester 70PA manufactured by Kyoeisha Chemical Co., Ltd)/GMA/St/AA=20/40/5/20/15

150 g of DMEA was charged in a reaction vessel of nitrogen atmosphere, and the temperature was raised to 80° C. by using an oil bath. To DMEA, a mixture comprising 20 g of difunctional epoxy acrylate monomer (epoxy ester 3002A), 40 g of difunctional epoxy acrylate monomer (epoxy ester 70PA), 20 g of St, 15 g of AA, 0.8 g of 2,2′-azobisisobutyronitrile, and 10 g of DMEA was added dropwise in 1 hour. After completing the dropwise addition, polymerization reaction was allowed to take place for another 6 hours. 1 g of hydroquinone monomethyl ether was then added to terminate the polymerization reaction, and a mixture comprising 5 g of GMA, 1 g of triethylbenzylammonium chloride, and 10 g of DMEA was then added dropwise for 0.5 hours. After the completion of the dropwise addition, the mixture was then allowed to undergo an addition reaction for 2 hours. The resulting reaction solution was purified by using methanol to remove the impurity which had not undergone the reaction, and the solution was dried under vacuum for another 24 hours to obtain photosensitive organic compound (4). The photosensitive organic compound (4) had an acid value of 101 mg KOH/g.

### [Thermosetting Compound]

Epoxy resin (1) (ADEKA Resin EP-4530 (epoxy equivalent, 190) manufactured by ADEKA)

Epoxy resin (2) (JER1001 (epoxy equivalent, 475); manufactured by Mitsubishi Chemical Corporation)

### [Pigment]

The one described in Table 1 (the volume average particle diameter was measured by a dynamic light scattering-type particle size distribution measurement system (manufactured by HORIBA, Ltd.))

### [Electroconductive Powder]

Ag particles having a volume average particle diameter of 1 μm (the volume average particle diameter was measured as described for the pigment)

### [Photoinitiator]

IRGACURE (Registered trademark) 369 (manufactured by BASF) N-1919 (manufactured by ADEKA)

### [Solvent]

DMEA (manufactured by Tokyo Chemical Industry Co., Ltd.)

### Example 1

### (i) Photosensitive Light-Shielding Paste

16.5 g of photosensitive organic compound (1), 0.5 g of N-1919, 1.0 g of epoxy resin (1), and 10.0 g of DMEA were placed in a 100 ml clean bottle and mixed by using a rotary and revolutionary mixer “Awatori Rentaro (bubble removing kneader)” (Registered trademark) (ARE-310 manufactured by Thinky) to produce 28.0 g of resin solution.

The resulting resin solution (28.0 g) and 2.0 g of tricobalt tetroxide (volume average particle diameter, 0.8 μm) were mixed, and the mixture was kneaded by using three rolls (EXAKT M-50 manufactured by EXAKT) to obtain 30 g of the photosensitive light-shielding paste.

### (ii) Photosensitive Electroconductive Paste

17.5 g of photosensitive organic compound (1), 3.5 g of IRGACURE (Registered trademark) 369, 1.5 g of epoxy resin (1), 3.5 g of Light acrylate BP-4EA (manufactured by Kyoeisha Chemical Co., Ltd), and 19.0 g of DMEA were placed in a 100 ml clean bottle and mixed by using the rotary and revolutionary mixer as used in the above (i) to produce 45.5 g of resin solution.

The resulting resin solution (45.5 g) and 62.3 g of Ag particles (volume average particle diameter, 1 μm) were mixed, and the mixture was kneaded by using three rolls (EXAKT M-50 manufactured by EXAKT) to obtain 77.8 g of the photosensitive electroconductive paste.

The patterning ability, the line resistance, the light-shielding property, and the adhesion to the substrate were evaluated by using the thus obtained photosensitive light-shielding paste and the photosensitive electroconductive paste. Table 2 shows the result of the evaluation. Line resistance of the laminated pattern was 350Ω.

### Examples 2 to 10

The evaluation was conducted as in the case of Example 1 except for the use of the photosensitive light-shielding paste having the composition shown in Table 1. The evaluation results are shown in Table 2.

It is to be noted that, for Example 10, a PET film substrate was used instead of the glass substrate.

### Examples 11 and 12

The evaluation was conducted as in the case of Example 1 except for the use of the photosensitive light-shielding paste having the composition shown in Table 1, use of the PET film substrate instead of the glass substrate, and use of the irradiation of the xenon flash lamp light beam in the evaluation of the patterning ability, the light-shielding property, and the adhesion to the substrate instead of the 30 minute heating (in the IR heater furnace at 140° C.). The evaluation results are shown in Table 2. It is to be noted that the xenon flash lamp light beam was irradiated under the conditions including an energy quantity of 1 J/cm² and an irradiation time of 0.5 msec.

### Comparative Examples 1 and 2

The evaluation was conducted as in the case of Example 1 except for the use of the photosensitive light-shielding paste having the composition shown in Table 1. The evaluation results are shown in Table 2.

In the Examples 1 to 12 satisfying the requirements of the present invention, production of excellent laminated patterns having low resistance, fineness, and good light-shielding property was possible.

TABLE 1

| | | Thermosetting compound | | | | |
|---|---|---|---|---|---|---|
| | | | Amount added in relation | Pigment | | |
| | | | to 100 parts by mass of | Amount added in | | |
| | Photo-sensitive | | the photo-sensitive | relation to the | | Volume average |
| | organic compound | | organic compound | entire solid content | | particle diameter |
| | Type | Type | (part by mass) | (% by mass) | Type | (μm) |
| Example 1 | (1) | Epoxy resin (1) | 6 | 10 | Co₃O₄ | 0.8 |
| Example 2 | (1) | Epoxy resin (1) | 10 | 15 | Co₃O₄ | 0.8 |
| Example 3 | (2) | Epoxy resin (1) | 10 | 20 | Co₃O₄ | 0.8 |
| Example 4 | (2) | Epoxy resin (1) | 30 | 30 | Co₃O₄ | 0.8 |
| Example 5 | (4) | Epoxy resin (2) | 30 | 50 | Co₃O₄ | 0.8 |
| Example 6 | (3) | Epoxy resin (1) | 30 | 5 | Co₃O₄ | 0.8 |
| Example 7 | (3) | Epoxy resin (1) | 30 | 20 | Carbon | 0.2 |
| | | | | | black | |
| Example 8 | (3) | Epoxy resin (1) | 40 | 20 | Ti | 1.0 |
| | | | | | black | |
| Example 9 | (4) | Epoxy resin (1) | 10 | 20 | MnO₂ | 1.0 |
| Example 10 | (4) | Epoxy resin (2) | 10 | 20 | Co₃O₄ | 0.8 |
| Example 11 | (4) | Epoxy resin (2) | 30 | 50 | Co₃O₄ | 0.8 |
| Example 12 | (1) | Epoxy resin (1) | 30 | 20 | Carbon | 0.2 |
| | | | | | black | |
| Comparative | (1) | — | — | 60 | Co₃O₄ | 0.8 |
| Example 1 | | | | | | |
| Comparative | (1) | — | — | 3 | Co₃O₄ | 0.8 |
| Example 2 | | | | | | |

| | Photoinitiator | | | |
|---|---|---|---|---|
| | | Amount added in relation | | |
| | | to 100 parts by mass of | Solvent | |
| | | the photo-sensitive | | Content in |
| | | organic compound | | the paste |
| | Type | (part by mass) | Type | (% by mass) |
| Example 1 | N1919 | 3 | DMEA | 33 |
| Example 2 | N1919 | 5 | DMEA | 50 |
| Example 3 | N1919 | 5 | DMEA | 50 |
| Example 4 | N1919 | 5 | DMEA | 50 |
| Example 5 | N1919 | 5 | DMEA | 50 |
| Example 6 | N1919 | 5 | DMEA | 50 |
| Example 7 | “IRGACURE” | 5 | DMEA | 30 |
| | 369 | | | |
| Example 8 | “IRGACURE” | 5 | DMEA | 60 |
| | 369 | | | |
| Example 9 | “IRGACURE” | 5 | DMEA | 40 |
| | 369 | | | |
| Example 10 | N1919 | 5 | DMEA | 40 |
| Example 11 | N1919 | 5 | DMEA | 50 |
| Example 12 | “IRGACURE” | 5 | DMEA | 30 |
| | 369 | | | |
| Comparative | “IRGACURE” | 5 | DMEA | 50 |
| Example 1 | 369 | | | |
| Comparative | “IRGACURE” | 5 | DMEA | 50 |
| Example 2 | 369 | | | |

TABLE 2

| | Property | | | | | | |
|---|---|---|---|---|---|---|---|
| | | | | | | Adhesion with | |
| | Line width increasing | | Straightness of | | | the substrate | |
| | of the pattern | | the pattern | Line | Light-shielding | Number of | |
| | Line width | Pass/ | Pass/ | resistance | ability | remaining | Pass/ |
| | (μm) | fail | fail | (Ω) | L* | squares | fail |
| Example 1 | 9 | Pass | Pass | 350 | 29 | 99 | Pass |
| Example 2 | 8 | Pass | Pass | 325 | 27 | 100 | Pass |
| Example 3 | 8 | Pass | Pass | 450 | 24 | 100 | Pass |
| Example 4 | 8 | Pass | Pass | 400 | 20 | 100 | Pass |
| Example 5 | 9 | Pass | Pass | 400 | 12 | 98 | Pass |
| Example 6 | 7 | Pass | Pass | 500 | 33 | 97 | Pass |
| Example 7 | 9 | Pass | Pass | 500 | 15 | 100 | Pass |
| Example 8 | 8 | Pass | Pass | 420 | 20 | 100 | Pass |
| Example 9 | 8 | Pass | Pass | 430 | 16 | 100 | Pass |
| Example 10 | 8 | Pass | Pass | 420 | 20 | 100 | Pass |
| Example 11 | 8 | Pass | Pass | 480 | 20 | 99 | Pass |
| Example 12 | 8 | Pass | Pass | 540 | 20 | 98 | Pass |
| Comparative | >10 | Fail | Pass | — | 7 | 99 | Pass |
| Example 1 | | | | | | | |
| Comparative | >10 | Fail | Fail | — | 58 | 44 | Fail |
| Example 2 | | | | | | | |

1. A photosensitive light-shielding paste comprising a pigment, a photosensitive organic compound, and a thermosetting compound wherein proportion of the pigment in the entire solid content is 5 to 50% by mass.

2. A photosensitive light-shielding paste according to claim 1 wherein the pigment is an oxide of a metal selected from the group consisting of chromium, iron, cobalt, ruthenium, manganese, palladium, copper, nickel, magnesium and titanium, or a carbon black.

3. A photosensitive light-shielding paste according to claim 1 wherein the photosensitive organic compound and/or the thermosetting compound has a skeleton selected from the group consisting of bisphenol A skeleton, bisphenol F skeleton, biphenyl skeleton, and alicyclic skeleton.

4. A photosensitive light-shielding paste according to claim 1 wherein the photosensitive organic compound has a carboxyl group.

5. A process for producing a laminated pattern for a touch sensor comprising the steps of
a first coating step wherein a photosensitive light-shielding paste comprising a pigment, a photosensitive organic compound, and a thermosetting compound is coated on a substrate to form a light-shielding coating film,
a second coating step wherein a photosensitive electroconductive paste comprising an electroconductive powder, a photosensitive organic compound, and a thermosetting compound is coated on the light-shielding coating film to form an electroconductive coating film, and
a step of forming a laminated pattern wherein the light-shielding coating film and the electroconductive coating film are together exposed and developed, and then subjected to either heating to a temperature of 100 to 300° C. or irradiation by a light beam of xenon flash lamp to thereby form the laminated pattern comprising a light-shielding layer and an electroconductive layer.

6. A process for producing a laminated pattern for a touch sensor according to claim 5 wherein the line width of the laminated pattern is 2 to 9 μm.

7. A touch sensor having the laminated pattern for a touch sensor produced by the production process of claim 5.

8. A touch screen having the touch sensor of claim 7.
